(19) United States
(12) Patent Application Publication
(10) Pub. No.: US 2011/0308457 A1
(43) Pub. Date: Dec. 22, 2011

(54) APPARATUS AND METHOD FOR TREATING AN OBJECT

(75) Inventors: Marcel Simor, Zoetermeer (NL); Paul Petrus Maria Blom, Veldhoven (NL)

(73) Assignee: NEDERLANDSE ORGANISATIE VOOR TOEGEPASTNATUURWETENS CHAPPELIJK ONDERZOEK TNO, Delft (NL)

(21) Appl. No.: 13/142,557

(22) PCT Filed: Dec. 29, 2009
(86) PCT No.: PCT/NL2009/050810

§ 371 Date: Sep. 7, 2011

(30) Foreign Application Priority Data
Dec. 30, 2008 (EP) 08173103.6

(51) Int. Cl. C23C 16/50

(52) U.S. Cl. 118/719; 118/723 R

(57) ABSTRACT

The invention relates to an apparatus for treating an object using a plasma process. The apparatus comprises a plasma reactor including a metal cylinder covered by a dielectric layer. Further, the apparatus comprises an electrode structure arranged radially outside the metal cylinder for generating the plasma process. The apparatus also comprises a supporting structure for locating the object to be treated at a pre-defined distance from the plasma reactor.

The invention relates to an apparatus for treating an object using a plasma process.

Presently, an atmospheric plasma technology is being developed worldwide for different applications such as coatings on glass, barrier coatings on electronics and packaging, improvement of textiles and paper with respect to dyeability, printability, adhesion properties, dirt repellency and flame resistance/retardancy.

With respect to atmospheric plasma technology, an industrial need exists for cost reduction of industrial production processes, add-on functionality on treated materials; environmentally friendly technology; large industrial scale atmospheric plasma systems. Further, there is a need for atmospheric plasma systems meeting requirements of providing a homogeneous plasma across a large surface, a stable plasma, independent of a process gas type, short treatment times and low power consumption.

In the past, the formation of stable and homogeneous low temperature plasmas was only possible at reduced pressure. The use of low pressure plasmas requires vacuum equipment, which requires high investment costs. Secondly, vacuum equipment is also difficult to incorporate in a production line, because the treated product needs to be loaded and unloaded into the vacuum chamber using load locks. This prohibits a continuous production process and reduces the production speed.

Recently industry is using volume dielectric barrier discharges (VDBD) as an alternative to create stable homogeneous low temperature plasma's at atmospheric pressure. In the case of VDBD the plasma of filamentary form (micro discharges also called “streamers”) is generated in volume by applying a high frequency and high voltage signal to an electrode that is separated from a grounded plane by a discharge gap and an insulating layer (dielectric barrier). The treated material, for example textile, is usually localized on the surface of dielectric barrier. The main drawback of a VDBD device used e.g. for the textile treatment is that chemically active environment is achieved only in the streamers, which develop perpendicularly to the treated textile. The consequence is that plasma is only in limited contact with the fabric surface which limits the efficiency of the treatment and thus reduces the processing speed. Furthermore, streamers tend to use repeatedly the same incompletely de-ionized micro discharge channels which can lead to a damage of the treated material (formation of pinholes in the treated material). To overcome this damage either higher speeds are required (results in even less efficient treatment) or higher flows of gases. Conclusion—VDBD is less suitable for a treatment of heat-sensitive materials like foils and textiles, or for treatment where high homogeneity and high efficiency is required. To overcome this problem an atmospheric pressure glow discharge (APGD) can be used, offered by e.g. Dow Corning Plasma; no pinholes are formed as a homogeneous glow plasma is formed. However, the APGD can only be generated in specific types of gas (for example nitrogen of very high purity or helium), and the gas flow needs to be high and power levels relatively low to maintain a stable plasma.

A particular type of DBD is known as Surface Dielectric Barrier Discharge (SDBD). In contrast to Volume Dielectric Barrier Discharges (VDBD) where the plasma develops in a gas gap in between two surfaces (at least one is covered by a dielectric layer), in SDBD electrode configurations the electrodes are integrated with a single solid dielectric structure thereby creating a plasma which is concentrated on the dielectric surface of this structure. Such a low-temperature plasma has significant benefits compared to traditional wet-chemistry finishing. Only a thin surface layer is modified by plasma treatment, and therefore desired surface properties can be achieved in various substrates without changing the bulk material characteristics. Such treatment enables the achievement of high-quality surface characteristics with results that are beyond the reach of traditional (wet chemical) materials processing. Last but not least, plasma processing is a dry and environmentally friendly technique. It does not require a vast supply of water, heating or drying, and only minute amounts of chemicals are necessary to reach the desired functionality.

The discharge structure includes streamers (also called micro-discharges), mainly developing on the dielectric in the same direction parallel to each other. In order to sustain SDBD plasma continuously, alternating polarity voltage or a series of pulses must be applied to the electrodes. During each change of the voltage-time gradient dV/dt streamers of the opposite polarity are generated on the dielectric. As result of the repulsive Coulomb force between streamers having the same excess charge, the branches never overlap each other. There appears to be an approximate linear relationship between the peak value of the applied voltage and streamer length. The physical properties of SDBD plasma of known electrode configurations have been widely studied through experiment and numerical modelling.

When comparing SDBD with VDBD and APGD technologies, the following can be noted. SDBD has a streamer-like nature like the VDBD on a microscopic scale but due to the built-up charge on the surface of a dielectric from one streamer, a developing path of next streamer is not identical with the path of the previous one (it is adjacent) so that the discharge is macroscopically uniform and the treatment is homogeneous. Furthermore, and in contrast to VDBD, streamers are parallel to the fabric surface, which result in a good contact between plasma and the treated material and, therefore, to higher efficiency i.e. relatively short treatment times. As plasma is not generated in volume but only where the treated material is, i.e. in a thin layer on the surface of dielectric barrier, more efficient operation and lower power consumption is associated with SDBD compared to VDBD. Further, as plasma is not generated in volume but only where the treated material is, i.e. in a thin layer on the surface of dielectric barrier, rest products of plasma polymerization (deposition) will only be present on the surface of the dielectric, which can easily be cleaned. SDBD is characterized by high density plasma compared to VDBD or other forms of non-thermal plasmas. The high density of chemically active environment is another factor that makes the treatment more efficient and may lead to even shorter treatment times.

In contrast to VDBD, APGD and other plasma sources, SDBD is stable at atmospheric pressure at almost any composition of the process gas and precursor (even at relatively relatively high concentration) and at high electrical power. In addition, in contrast to VDBD and APGD, SDBD is stable at low flow rates of gas, and is even stable when no gas flow is present. SDBD plasma penetrates into (the pores of) the fabric and, unlike to VDBD and other plasma sources, the treatment is not just on the outer surface of material but both the surface and the inside of the fabric (on the level of individual fibers if applicable) are treated.

However, no plasma system is currently known that is suitable for applying a large industrial scale atmospheric plasma process.

It is an object of the invention to provide an apparatus according to the preamble, wherein at least one of the disadvantages identified above is reduced. In particular, the invention aims at obtaining an apparatus according to the preamble enabling large industrial scale atmospheric plasma processes. Thereto, the apparatus according to the invention comprises a plasma reactor including a metal cylinder covered by a dielectric layer, an electrode structure arranged radially outside the metal cylinder for generating the plasma process, and a supporting structure for locating the object to be treated at a pre-defined distance from the plasma reactor, wherein the electrode structure comprises an electrode element that is arranged on or in the dielectric layer.

By providing a plasma reactor including a metal cylinder covered by a dielectric layer, an electrode structure arranged radially outside the metal cylinder for generating the plasma process, and a supporting structure for locating the object to be treated at a pre-defined distance from the plasma reactor, a low temperature homogeneous plasma may be generated across a relatively large surface, so that large industrial scale atmospheric plasma processes can be applied. The plasma might be stable and independent of a particular process gas, enabling short treatment times, a relatively low power consumption while potentially combining high throughput with low yield loss.

By the term “plasma” is meant a partially ionized gas that represents a chemically active environment comprising activated species such as electrons, ions, vibrational and electronic excited states, radicals, metastables and photons. The proposed apparatus is preferably applied using gas flows at approximately atmospheric pressure. However, gas flows at reduced pressure or super atmospheric pressure, in the range 0.1-2 bar, can be effectively applied as well.

Other advantageous embodiments according to the invention are described in the following claims.

By way of example only, embodiments of the present invention will now be described with reference to the accompanying figures in which

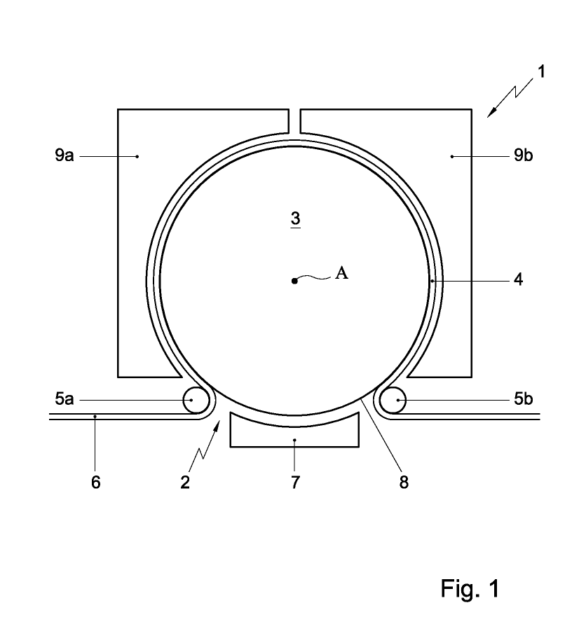

FIG. 1 shows a schematic side view of a first embodiment of an apparatus according to the invention;

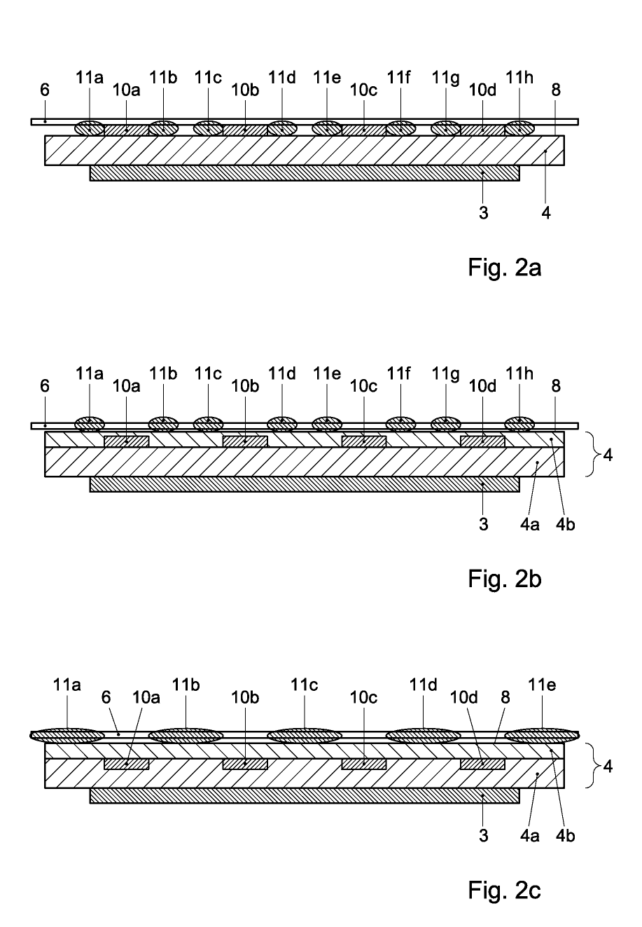

FIG. 2a shows a schematic side view of a surface section of a first embodiment of the apparatus' reactor shown in FIG. 1;

FIG. 2b shows a schematic side view of a surface section of a second embodiment of the apparatus' reactor shown in FIG. 1;

FIG. 2c shows a schematic side view of a surface section of a third embodiment of the apparatus' reactor shown in FIG. 1;

FIG. 2d shows a schematic side view of a surface section of a fourth embodiment of the apparatus' reactor shown in FIG. 1;

FIG. 2e shows a schematic side view of a surface section of a fifth embodiment of the apparatus' reactor shown in FIG. 1;

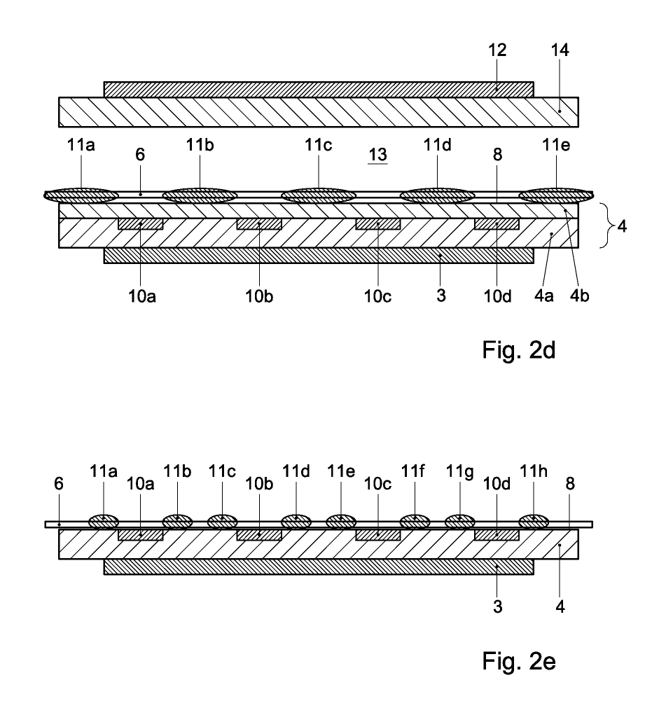

FIG. 3a shows a schematic side view of a surface section of a sixth embodiment of the apparatus' reactor shown in FIG. 1;

FIG. 3b shows a schematic side view of a surface section of a seventh embodiment of the apparatus' reactor shown in FIG. 1; and

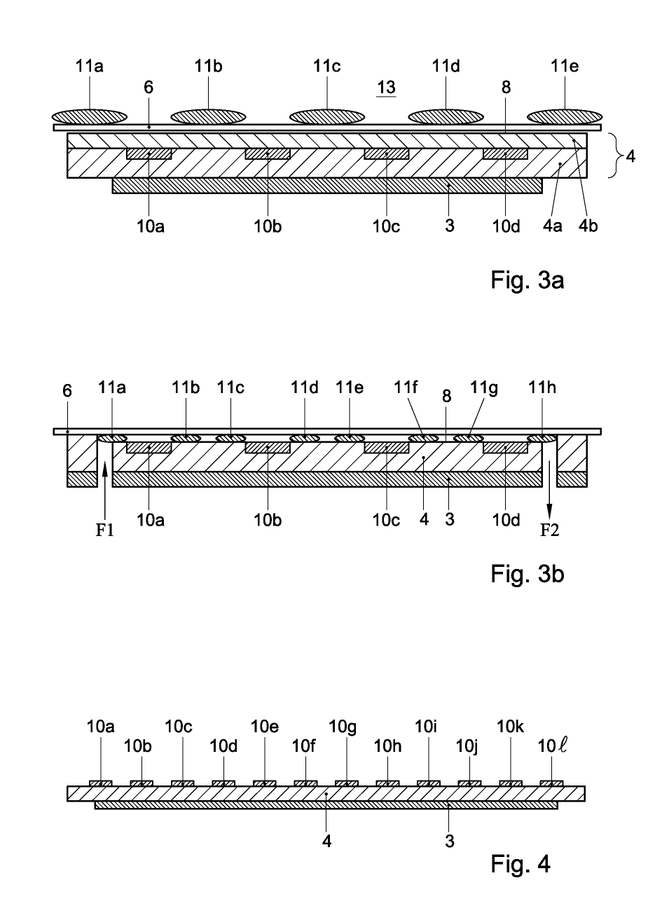

FIG. 4 shows a schematic side view of a partial electrode structure in the apparatus' reactor shown in FIG. 1.

The figures are merely schematic views of preferred embodiments according to the invention. In the figures, the same reference numbers refer to equal or corresponding parts.

FIG. 1 shows a schematic side view of a first embodiment of an apparatus 1 according to the invention. The apparatus 1 is arranged for treating an object using a plasma process. Thereto, the apparatus 1 comprises a plasma reactor 2 including a metal cylinder 3 covered by a dielectric layer 4. Further, the apparatus 1 comprises an electrode structure arranged radially outside the metal cylinder 3 for generating the plasma process. The electrode structure is discussed below referring to FIGS. 2, 3 and 4. In addition, the apparatus 1 comprises a supporting structure for locating the object to be treated at a pre-defined distance from the plasma reactor 2. The supporting structure comprises two guiding rollers 5a,b for guiding the object 6 along a top surface 8, also called outer surface of the reactor 2. In the embodiment shown in FIG. 1, the object 6 touches the top surface 8, so that the pre-defined distance is circa 0 mm. However, also other pre-defined distances are applicable. By providing two or more guiding rollers 5a,b the object, also called substrate, to be treated, such as a two-dimensional textile structure, can be handled easily and reliably along the top surface 8 of the reactor 2. In principle, also other supporting structures can be used, such as gripping elements and/or radially extending members arranged on the reactor for guiding the object 6 at a pre-defined distance from the top surface 8 of the reactor 2.

The reactor comprises a rotating axle A and a driving unit (not shown) for rotating the reactor over the rotating axle A. In an alternative embodiment, the reactor is rotatably driven by the substrate 6 that is fed along the outer surface 8 of the reactor 2. In yet a further embodiment, the reactor is not provided with a rotating axle. Then, the reactor 2 is fixed so that the object slides along the outer surface 8 of the reactor 2.

During operation of the apparatus 1, a low temperature atmospheric surface dielectric barrier discharge (SDBD) plasma is created along a substantial part of the outer surface 8 of the cylindrical plasma reactor. The plasma is created by applying a voltage differential between electrode structure elements. Here, the plasma process can advantageously be performed under substantially atmospheric pressure, thereby reducing costs for providing low pressure circumstances at the locus of the object to be treated.

The cylindrical plasma reactor rotates. The substrate 6 moves along the cylinder top surface 8, preferably at a slightly lower or higher speed to obtain a homogeneous treatment of the substrate 6. Alternatively, if the substrate 6 and the cylinder top surface 8 have the same circumferential speed the substrate may only be treated in between line-shaped electrodes of the electrode structure. The difference in velocity of the substrate and the cylinder surface is preferably be kept as small as possible to prevent abrasion of the substrate 6 and the cylinder top surface 8.

The apparatus 1 as shown in FIG. 1 comprises a multiple number of gas units 9a, 9b that are arranged in subsequent circumferential order with respect to the outer surface 8 of the reactor, so that different plasma processes may sequentially be applied when treating the object 6. Use of a segmented gas unit allows a multi-step treatment in one passage of the substrate. An example of such a multi-step treatment is plasma activation followed by plasma polymerization. The proposed plasma system is not limited to two segments as shown in FIG. 2, more than two segments can be used. The same effect can also be reached by using multiple plasma systems in series if appropriate and economically feasible.

The apparatus 1 further comprises a cleaning unit 7 for cleaning a top surface of the reactor 2. The cleaning unit 7 is located at a circumferential section of the reactor top surface 8 where the top surface of the reactor 2, during operation of the apparatus 1, is free of an object 6 to be treated and might be free of plasma if appropriate. The cleaning unit 7 is optional and may advantageously be used for cleaning the reactor top surface 8, possibly during operation of the apparatus 1. By cleaning the top surface 8 during the operation of the reactor, the down time is minimized and the yield loss is decreased.

The cleaning unit for cleaning contaminant particles from the top surface 8 may comprise a brush, and/or a solvent dispenser and/or a separate flame or plasma unit or their combination for cleaning the reactor top surface 8 mechanically, chemically and/or physically, respectively. Plasma generated on the top surface 8 in a special atmosphere might be also used for the cleaning. As an example, a CF₄/O₂/Ar gas mixture may be used to remove SiOₓ contaminants.

The plasma apparatus enables the treatment of two-dimensional substrates at an industrial scale and with velocities which are standard in the process industry. Examples of such two-dimensional substrates are: closed surfaces like plastic foil, porous materials like paper and dense textiles; open structures like “open” textiles; and arrays of filament-like materials. The plasma may be used for a number of proven applications such as: plasma cleaning and etching for removal of material from the treated surface, plasma activation for introducing new functional groups onto the treated surface, plasma polymerization wherein a monomer is introduced directly into the plasma and the polymerization occurs in the plasma itself, plasma induced polymerization, plasma-assisted grafting wherein during a two-step process plasma activation is followed by the exposure to a precursor, e.g. a monomer, wherein the monomer then undergoes a conventional free radical polymerization on the activated surface.

FIG. 2a shows a schematic side view of a surface section of a first embodiment of the apparatus' reactor 2 shown in FIG. 1. For reasons of simplicity, the cylindrical structure is depicted as a planar structure. The metal cylinder 3, acting as a ground electrode, has been covered with a dielectric layer 4. The electrode structure comprises a multiple number of electrode elements 10a-d that are arranged on the dielectric layer 4. During operation of the apparatus 1, surface DBD plasmas 11a-h are generated by applying voltage differentials to the electrode elements 10a-d. The substrate 6 to be treated is positioned above and near the electrodes 10a-d so that the plasmas 11a-h may penetrate into the substrate 6.

FIG. 2b shows a schematic side view of a surface section of a second embodiment of the apparatus' reactor shown in FIG. 1. Here, the electrodes 10a-d have been embedded in the dielectric layer 4. The dielectric layer is composed of two sub-layers 4a, 4b functionally forming a single dielectric structure protecting the high-voltage electrodes from erosion during operation.

FIG. 2c shows a schematic side view of a surface section of a third embodiment of the apparatus' reactor shown in FIG. 1. The depicted electrode structure is known as a co-planar SDBD structure. The subsequent electrode elements 10a-d are alternatingly connected to ground and high voltage signal electrodes. The generated plasmas are mainly located just above the dielectric layer 4.

Further, FIG. 2d shows a schematic side view of a surface section of a fourth embodiment of the apparatus' reactor shown in FIG. 1. Here, the configuration shown in FIG. 2c has been supplemented with a secondary electrode element located radially outside and remote from the dielectric layer 4 above the primary electrodes 10a-d for creating a semi-volume discharge. A further, optional dielectric layer 14 is located between the secondary electrode 12 and a receiving space 13 between the dielectric layer 4 and the secondary electrode 12.

FIG. 2e shows a schematic side view of a surface section of a fifth embodiment of the apparatus' reactor shown in FIG. 1. The electrode elements 10a-d are located inside the dielectric layer 4 just below the top surface 8 of the reactor 2.

The reactor 2 can be manufactured by providing a metal cylinder preferably having a large diameter and a large longitudinal dimension. The metal cylinder may serve as a ground electrode. A plasma or thermal spraying process can be used to deposit the dielectric layer, e.g. a ceramic coating, on the metal cylinder. Further, the metal electrodes may be deposited on or in the dielectric layer, e.g. by applying a plasma spraying technique, thus providing a reliable and cheap manufacturing process. A ceramic layer may be subjected to machining operations, such as masking, grinding and/or polishing to locate the electrodes properly.

The electrode structures shown in FIG. 2a-e are especially suitable for treating “open” textiles and arrays of filament-like materials.

FIGS. 3a and 3b show a schematic side view of a surface section of a sixth and seventh embodiment of the apparatus' reactor shown in FIG. 1. The latter two embodiments are suitable for treating “closed” surfaces like plastic foil, porous materials like paper and dense textiles. The electrode structure in FIG. 3a is similar to the structure shown in FIG. 2c, however, the dimensions and applied voltage differentials are chosen such that the plasmas will be created on top and/or into the substrate 6. In this case the substrate itself may be used as the dielectric material. In case discharge activity might occur between the plasma reactor and the bottom side of the substrate extra measures may be needed. Possible solutions are the use of e.g. argon as a base gas or an admixture gas or use of a sub-atmospheric pressure to lower the excitation energy of the plasma above the substrate. A lower voltage can then be used to produce a plasma above the substrate, and the occurrence of a plasma between the reactor and substrate will be counteracted. When the substrate is firmly attached to the electrode, it may serve as a dielectric and no plasma may occur between the substrate and the electrode, so that no special countermeasures are needed apart from a good substrate fixation system.

In the structure shown in FIG. 3b, the supporting structure comprises radially extending members 16a, 16b arranged on the outer surface of the reactor for guiding the object at a pre-defined distance from the top surface of the reactor. Here, the pre-defined distance is not 0 mm, but may e.g. be in a range from 0.1 mm to several millimetres. A slit 15a in the cylinder 3 is present to guide a gas flow Fl towards the object to be treated. Process gas including precursors and/or nano-particles may be injected in space between the substrate 6 and the plasma reactor. The process gas can be a mixture of a high volume gas (e.g. He, Ar, Xenon, N₂, O₂, CO₂, NO, steam or air) and an additional gas or evaporated precursor (e.g. air, helium, neon, argon, chlorine, hydrogen bromide, silane, carbon tetrafluoride, freon, sulphur hexafluoride, hydrogen, ammonia, tetraethosiloxane, oxygen, carbon dioxide, water, HMDSO, TEOS). Nano-particles can be selected from a wide range of commercially available products (e.g. SiOₓ, TiO₂). Further, the reactor may comprise multiple gas flow paths for separately flowing materials towards the object. Here, the plasma is created between the top surface 8 of the cylinder and the substrate 6. It is noted that the step of injecting one or multiple process gases in a space between the substrate 6 and the plasma reactor can also be applied in other embodiments according to the invention. As an example, the process gases may be injected laterally from a direction transverse to the moving direction of the substrate 6. Optionally, the structure is provided with a secondary electrode element as shown in FIG. 2d in order to stimulate discharge activities on top of the substrate 6.

Optionally, the apparatus 1 further comprises multiple gas flow paths F1-F2 for separately flowing different materials towards and/or from the object 6. Downstream sections of at least two gas flow paths of the multiple gas flow paths F1-F2 may substantially coincide, thereby allowing materials of the separate flow paths to mix. As an example, two gas flow paths separately flow towards the substrate, while a single flow path flows away from the substrate. Preferably, the substantially coinciding downstream sections of the at least two gas flow paths are located near the object, so that a desired particle composition does not need travelling a long distance before reaching the object to be treated. As a result, an efficient treating process is obtained.

The treated substrate 6 can be a foil. However, also other substrates can be treated, e.g. high density membranes and paper.

FIG. 4 shows a schematic side view of a partial electrode structure in the apparatus' reactor shown in FIG. 1. In FIG. 4, every 6^{th} high-voltage electrode belongs to the same group of electrodes 10a-l. As such, the electrode structure comprises an interconnection conducting pattern wherein a multiple number of electrodes are electrically interconnected. In an implementation, a group of electrodes can consist of any possible number of high-voltage electrodes. Every group of electrodes is separately controlled by a high-voltage source. As a first example, the total amount of high-voltage electrodes is 900. If there is 1 group of electrodes, this group has 900 high-voltage electrodes in parallel and only this 1 group of electrodes can be switched on/off as a whole.

As a second example, the total amount of high-voltage electrodes is again 900. If there are 100 groups of electrodes, every group has 9 high-voltage electrodes in parallel and 100 groups of electrodes can be switched on/off separately. As a third example, the total amount of high-voltage electrodes is 900 again. If there are 900 “groups of electrodes”, every “group of electrodes” has 1 high-voltage electrode, which means that every high-voltage electrode can be switched on/off separately.

If a breakdown occurs in the dielectric layer 4 between the high-voltage electrode 10 and the grounded electrode 3 the entire plasma reactor would become useless if all discharge lines are activated as one group, see e.g. the first example mentioned above. In order to counteract this type of problem and to increase the lifetime of the reactor every metal discharge line (or group of lines) may be activated separately by the high-voltage source, see e.g. the second and third example mentioned above. When a break down occurs between one of the discharge lines (or group of lines) and the grounded electrode, this section of the plasma reactor shall be switched off, hereby increasing the life time of the plasma reactor as a whole.

To maintain a homogeneous treatment of the substrate the cylinder speed may be increased or decreased with respect to the substrate. To maintain the same treatment time the speed of substrate needs to be reduced. As a consequence, eventual production processes before or after the plasma processing might be negatively influenced. A possible way to counteract this is to have one or more spare, inactive, groups of electrodes on the plasma reactor as in the embodiment shown in FIG. 4. In case one group of electrodes fails this group is/can be switched off and a spare group of electrodes is/can be switched on. As a consequence, the speed of the substrate may remain the same hereby having no (negative) influence of other production processes.

Generally, the plasma system is part of a production process wherein different production steps follow each other. The speed of the substrate is often determined by other production steps before or after the plasma system. The variable plasma parameters, e.g. voltage amplitude, frequency for AC plasma, pulsed width and repetition rate for a pulsed plasma, process gas, precursors and nano-particle content, and the invariable system parameters, e.g. diameter of the plasma reactor, number of plasma reactors, are optimized with respect to the speed of the substrate and thus by the process as a whole. In case the process requires, e.g. for a short period of time, a lower or higher substrate velocity the plasma intensity may decrease or increase by adjusting variable plasma parameters. However, this might change the chemistry of the plasma process. The latter effect might be counteracted by switching off one or more group of electrodes or by switching on one or more of the spare, inactive, group of electrodes.

In this respect it is noted that the electrode structure comprising an interconnection conducting pattern wherein a multiple number of electrodes are electrically interconnected, can not merely be used in combination with a plasma reactor including a metal cylinder covered by a dielectric layer, wherein the electrode structure is arranged radially outside the metal cylinder for generating the plasma process, but also, more general, in combination with any plasma reactor including a dielectric layer, e.g. a flat layer, wherein the electrode structure is associated with the dielectric layer for generating the plasma process.

To drive the SDBD plasma reactor different types of high-voltage sources, e.g. AC, pulsed or any combination, can be applied. Additional functionality may be added to the power supply/supplies to activate group of electrodes or single electrodes separately as described above.

The invention is not restricted to the embodiments described herein.

As an example, various shapes of electrodes on the solid dielectric structure of the plasma units can be implemented.

Further, as an option, SDBD plasma treatment at two opposite sides of an object to be treated can be realized by implementing a similar arrangement of plasma units on the opposite side of the object.

Optionally, the reactor may be provided with a cooling unit for cooling the top surface of the reactor so as to remove excessive heat produced by plasma process.

Further such variants will be obvious for the man skilled in the art and are considered to lie within the scope of the invention as formulated in the following claims.

1. An apparatus for treating an object using a plasma process, comprising
a plasma reactor including a metal cylinder covered by a dielectric layer,
an electrode structure arranged radially outside the metal cylinder for generating the plasma process, and
a supporting structure for locating the object to be treated at a pre-defined distance from the plasma reactor, wherein the electrode structure comprises an electrode element that is arranged on or in the dielectric layer,
and wherein the electrode structure is arranged for generating a streamer SDBD plasma.

2. An apparatus according to claim 1, wherein the electrode structure comprises a secondary electrode element arranged radially outside and offset from the dielectric layer.

3. An apparatus according to claim 1, wherein the electrode structure comprises an interconnection conducting pattern wherein a multiple number of electrodes are electrically interconnected.

4. An apparatus according to claim 1, wherein the supporting structure comprises a guiding roller for guiding the object along a top surface of the reactor.

5. An apparatus according to claim 1, wherein the supporting structure comprises a radially extending member arranged on the reactor for guiding the object at a pre-defined distance from a top surface of the reactor.

6. An apparatus according to claim 1, wherein the reactor comprises multiple gas flow paths for separately flowing materials towards the object.

7. An apparatus according to claim 6, wherein downstream sections of at least two gas flow paths of the multiple gas flow paths substantially coincide.

8. An apparatus according to claim 1, wherein the reactor comprises a rotating axle and a driving unit for rotating the reactor over the rotating axle.

9. An apparatus according to claim 1, further comprising a cleaning unit for cleaning a top surface of the reactor, wherein the cleaning unit is located at a circumferential position where the top surface of the reactor, during operation of the apparatus, is free of objects to be treated.

10. An apparatus according to claim 1, wherein the cleaning unit comprises a brush, a solvent dispenser, flame gun/torch and/or a separate plasma unit.

11. An apparatus according to claim 1, wherein the reactor comprises a cooling unit for cooling the top surface of the reactor.

12. An apparatus according to claim 1, further comprising a multiple number of gas units that are arranged in subsequent circumferential order.
